(19) United States
(12) Patent Application Publication
(10) Pub. No.: US 2019/0199306 A1
(43) Pub. Date: Jun. 27, 2019

(54) AMP SYSTEM FOR VEHICLE USING BLUETOOTH MODULE

(71) Applicant: Hun Sop YUM, Mapo-gu, Seoul (KR)

(72) Inventor: Hun Sop YUM, Mapo-gu, Seoul (KR)

(21) Appl. No.: 13/881,142

(22) PCT Filed: Jan. 7, 2013
(86) PCT No.: PCT/KR13/00070

§ 371 Date: Apr. 23, 2013

(30) Foreign Application Priority Data
Oct. 19, 2012 (KR) 10-2012-0116527

(51) Int. Cl. H03F 3/68; H03F 3/04; B60R 11/02; H04W 4/80

(52) U.S. Cl. CPC H03F 3/68; H03F 3/04; H03F 2200/03; H04W 4/80; B60R 11/02

(57) ABSTRACT

An amp system for vehicle using bluetooth module is disclosed. The amp system comprising: a main body; a power supply terminal for receiving electric current from an external power source; a bluetooth-receiving module for receiving an audio signal from a bluetooth transmission module embedded in a mobile communication terminal of a user; a PCB with a device for amplifying the received audio signal; an output terminal for delivering the amplified audio signal to a speaker; and the speaker for receiving the amplified audio signal from the output terminal and generating sound, enables that by installing the bluetooth module in the amp for vehicle and communicating with user's mobile communication terminal using bluetooth communication, amplifies music or phone call sound from the mobile communication terminal through the amp for vehicle and outputs it through the speaker in vehicle.

### FIELD OF TECHNOLOGY

The present invention relates to an amp system for vehicle using a bluetooth module.

### BACKGROUND OF THE INVENTION

An external amp for vehicle is used for amplifying audio of an audio system for a vehicle. That is, the amp for vehicle receives audio signal from a main body of the audio system, amplifies, and outputs it to a speaker.

In general, an amp for vehicle includes a head unit and a speaker, which replays on a media such as radio broadcasting, cassette tape, CD, or DVD and allows a user to enjoy music.

The head unit, in which a radio receiver, cassette player, CD player, etc. are combined, is configured to be controlled easily while driving, and usually installed around the dash board of the vehicle. However, in general, the embedded amplifier of the head unit installed in a car as a basic item has a output rating of 18-40 W, which is not enough to enjoy a powerful sound because a clipping phenomenon takes places above 80% of maximum volume.

Accordingly, a separate amp for vehicle for generating sound of high quality in a car has been well known. The amp for vehicle is a power amp that amplifies of the audio output of the head unit and then outputs it to a separate speaker of high power, and usually is provided as an external one. In a Korean Patent No. 0968203 (Title of Invention: Audio System for vehicle) is disclosed an audio system for vehicle including a head unit and an external amp.

An external amp for vehicle is connected to the head unit using wire, receives audio signal, and is applied with a power by being connected to a car battery. That is, in general, the amp for vehicle is connected to the car battery and speaker through a power cable and a speaker cable, respectively, since it is large and heavy.

However, according to the prior arts, since an amp for vehicle receives mainly the signal of audio system for vehicle only and then outputs, even though the user has various types of audio sources, there is a problem that the user cannot execute and enjoy music conveniently.

The above conventional technology was owned by the inventor for contriving the present invention or ones which the user learned in the process of contriving of the present invention, it is not necessarily prior arts that were disclosed to the public before the present invention.

### DETAILED DESCRIPTION OF INVENTION

### Problems to Solve

The present invention provides an amp system for vehicle using bluetooth module, which amplifies music or phone call sound of a mobile communication terminal using an amp for vehicle ad then outputs it to a speaker inside the car by providing a bluetooth module and enabling to communicate directly with a mobile communication terminal.

The technological problems other than what the present invention suggested are going to be understood easily by the description given below.

### Solutions to Problems

An amp system for vehicle using bluetooth module is provided, and the amp system comprises: a main body; a power supply terminal disposed at a side of the main body and for receiving electric current from an external power source; a bluetooth-receiving module for being powered by the electric current and receiving an audio signal from a bluetooth transmission module embedded in a mobile communication terminal of a user in a vehicle; a PCB with a device for amplifying the received audio signal using the electric current; an output terminal for delivering the amplified audio signal to a speaker; and the speaker for receiving the amplified audio signal from the output terminal and generating sound.

Here, when the mobile communication terminal receives a phone-call data while transmitting a music signal for the audio signal, the mobile communication terminal may stop the transmission of the music signal and transmit a phone-connecting sound or a phone-call sound data corresponding to the phone-call data to the bluetooth-receiving module for the audio signal.

Also, the amp system for vehicle using bluetooth module may further comprise a switch for activating or deactivating a function that when the mobile communication terminal receives a phone-call data while transmitting a music signal for the audio signal, the mobile communication terminal stops the transmission of the music signal and transmits a phone-connecting sound or a phone-call sound data corresponding to the phone-call data to the bluetooth-receiving module for the audio signal.

Here, the output terminal may be a bluetooth module for transmitting a bluetooth signal, and the output terminal and the speaker may communicate with each other with the bluetooth module.

Also the main body may receive the PCB, be opened and closed by a main-body cover, provide heat sinks for radiating internal heat to outside on both sides thereof, and be installed in a trunk of the vehicle.

Here, the bluetooth receiving module may be attached to the main body detachably.

Aspects, features, and advantages other than the above description will be apparent from the drawings, claims, and detailed description of the present invention.

### Effects of Invention

An amp system for vehicle using bluetooth module according to the present invention has effects that amplifies music or phone call sound of a mobile communication terminal using an amp for vehicle ad then outputs it to a speaker inside the car by providing a bluetooth module and enabling to communicate directly with a mobile communication terminal.

### BRIEF DESCRIPTION OF THE DRAWINGS

FIG. 1 is a perspective view of an amp system for vehicle using bluetooth module according to an embodiment of the present invention.

FIG. 2 is a block diagram of an amp system for vehicle using bluetooth module according to an embodiment of the present invention.

FIG. 3 is a flowchart of operation of an amp system for vehicle using bluetooth module according to an embodiment of the present invention.

### DETAILED DESCRIPTION EMBODIMENTS OF THE INVENTION

Since the present invention can be modified in various ways and have various embodiments, certain embodiments would be shown in the figures and described in detail. But this is not limiting the invention to a certain types, and the invention should be understood to include all modifications, equivalents, or replacements, which belong to the spirit and technological range of the present invention.

Terms with ordinals such as first, second, etc. may be used to explain various parts, but the said parts are not limited by such terms. The said terms are used just to distinguish one part for other part.

When a certain part is described “connected” or “attached” to other part, it must be understood so that it is connected or attached directly to the other part, or that another part may exist between them.

The terms used in this specification is used just to explain a specific embodiment, not being intended to limit the invention. A singular expression includes a plural expression, unless specified otherwise. Terms such as “comprise”, “have”, etc. is for showing that features, numbers, steps, operations, parts, items, or their combinations exist, and it should be understood that it does not exclude the existence or possibility to augment of one or more other features, numbers, steps, operations, parts, items, or their combinations.

Also, the terms such as “ . . . member”, “ . . . module”, “ . . . means”, etc. mean a unit for handling at least one function or operation, and they can be realized by hardware, software, or their combination.

Also, in describing referring the figures, irrespective of reference numerals, a same part is assigned with a same reference numeral and repetitive explanations about it are omitted. In describing the present invention, in cases that a specific description on well-known related technology may blur the issues of the present invention unnecessarily, such description may be omitted.

### Structures for Embodiments of Invention

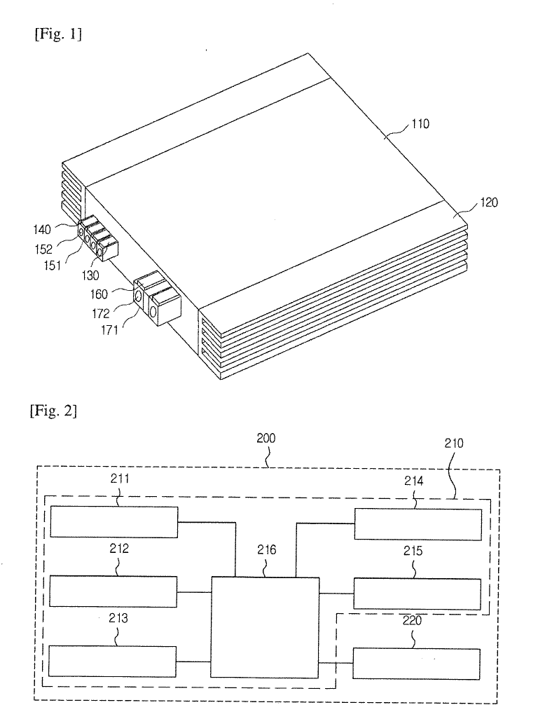

FIGS. 1 and 2 are a perspective view and a block diagram of an amp system for vehicle using bluetooth module according to an embodiment of the present invention, respectively.

The embodiment has features that amplifies music or phone call sound of a mobile communication terminal using an amp for vehicle ad then outputs it to a speaker inside the car by providing a bluetooth module and enabling to communicate directly with a mobile communication terminal.

Referring to FIG. 1, the amp for vehicle is a device which is supplied with electric current from an external power supply, amplifies audio signal, and outputs it to a speaker. For this, the amp for vehicle includes a power connector (160) for being supplied with power source, a audio input connector (130) for receiving audio signal from a main body of an audio system installed in the vehicle, and a terminal connector (140) for outputting the amplified audio signal to an external speaker.

The main body of the amp for vehicle, that is, the exterior case receives a PCB installed with a plurality of devices for amplifying signal, is opened and closed by a main-body cover (110), and includes a heat sink (120) on both sides thereof for radiating internal heat.

The terminal connector (140) is received by a transparent or translucent terminal-connector case (151), and protrudes toward outside. The number of the terminal connector (140)s may be plural, and the terminal connector (140)i is connected from the inside of the amp for vehicle to the PCB with wires so as to receive the amplified audio signal, and is connected to a speaker connector through a hole (152) outside so as to deliver the amplified audio signal. The speaker connector is connected to the speaker installed outside the vehicle through a speaker cable, and delivers electrical audio signal of high power that was generated by the amp for vehicle to the speaker.

Also, the power connector (160) is received by a transparent or translucent power connector case (171), protrudes toward outside, is supplied with power from an external power source through a hole (172), and delivers it to the PCB (180). Here, the external power source may be a car battery, and the power connector (160) is connected to the car battery through a power cable and supplies a DC current from the car battery to the amp for vehicle. In the power connector case (171) is provided a plurality of power connector (160)s.

Each of the terminal connector (140) and the power connector (160) is made of metal having conductivity, for example, iron, copper, aluminum, etc., or its surface may be coated.

In the PCB are installed various devices for amplifying the audio signal. For example, the devices may include a coil, a condenser, an FET, etc., and they can be categorized to operating devices such as switches, volumes, etc. for operating the amp for vehicle, and controlling devices such as coil, condenser, FET, etc.

In the main body may be installed a mobile communication terminal, a speaker, and a bluetooth module that can communicate with the main body of the audio system installed in the vehicle through bluetooth. When the bluetooth module communicates with the mobile communication terminal the audio signal is received from the mobile communication terminal, and when the bluetooth module communicates with the main body of the audio system installed in the vehicle the audio signal to amplify is received from the main body of the audio system, and when it communicates with the speaker the amplified audio signal may be transmitted to the speaker.

Here, the mobile communication terminal is a terminal for outputting the audio signal, and, for example, it may be one out of a smart phone, a PDA, a feature phone, etc.

Referring to FIG. 2, a amp system for vehicle (200) may include a amp for vehicle (210) and a speaker (220), and the amp for vehicle (210) may include main body (211), power connector (212), bluetooth receiving module (213), PCB (214), output connector (215), and control unit (216). The differences from the above description are going to be explained mainly.

The bluetooth receiving module (213) is supplied with electric current, and receives audio signal from a bluetooth transmitting module embedded in the mobile communication terminal of a user in the vehicle. Here, the audio signal may include a music signal or a phone-call signal from the mobile communication terminal.

The bluetooth is a wireless communication technology, which can transmit audio signal and file such as image between mobile communication terminals or between an electronic device including a mobile communication terminal and other electronic device.

The output connector (215) can deliver the amplified audio signal to the speaker. The output connector (215) may be a connector for connecting a wire cable if the amp for vehicle (210) and the speaker (220) are connected by wire, and it may be a bluetooth module for transmitting a bluetooth signal if the amp for vehicle (210) and the speaker (220) communicate with the bluetooth module.

The control unit (216) controls each parts such that the power connector (212), the bluetooth receiving module (213), the PCB (214), and the output connector (215) perform their own function while cooperating one another.

Here, if the mobile communication terminal receives phone-call data while transmitting music signal for the audio signal, it may stop the transmission of music signal and transmit a phone-connecting sound or phone-sound data corresponding to the phone-call data to the bluetooth receiving module (213) for the audio signal. That is, if the user executes a music file stored in the mobile communication terminal or linked to the Internet, the generated music signal may be transmitted to the bluetooth receiving module (213) of the amp for vehicle (210) using the bluetooth communication.

In such a case, if the mobile communication terminal receives the phone-call data while transmitting the music signal, it may include a switch for stopping the transmission of music signal and transmitting a phone-connecting sound or phone-sound data corresponding to the phone-call data to the bluetooth receiving module (213) for the audio signal. If the user turns on a corresponding activating switch, the phone-call signal generated during music playing is transmitted to the bluetooth receiving module (213), and otherwise the phone-call signal is not transmitted.

Also, the bluetooth receiving module (213) of the amp for vehicle (210) may further comprise a priority-determining switch for determining the priority order of audio signals received. For example, when the amp for vehicle (210) performs bluetooth communication with the mobile communication terminal and the main body of the amp for vehicle simultaneously, the priority-determining switch may be a switch for determining whether it receives the audio signal of the mobile communication terminal or the audio signal of the main body of the amp for vehicle. In order to determine it, the amp for vehicle (210) may further comprise a display and a controller. For example, the display outputs the list of objects connected to the bluetooth communication presently, and the controller may determine the priority of the received objects for the audio signal out of the list through the user's operation.

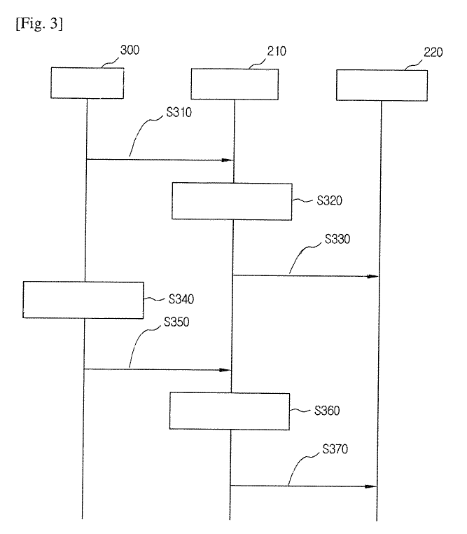

FIG. 3 is a flowchart of operation of an amp system for vehicle using bluetooth module according to an embodiment of the present invention. Each step to be described below does not have to be performed in that specific temporal order, and if the gist of the invention is satisfied even though the steps performed in different orders, of course, such procedures belong to the scope of the present invention.

In the step S310, the mobile communication terminal (300) transmits music signal to the amp for vehicle (210) using the bluetooth module. In the step S320, the amp for vehicle (210) amplifies the received music signal. In the step S330, the amp for vehicle (210) transmits the amplified music signal to the speaker (220).

In the step S340, the mobile communication terminal (300) stops the transmission of the music signal if receiving a phone-call data while transmitting the music signal to the amp for vehicle (210) continuously. Here, the phone-call data may be data received in transmitting or receiving a voice phone call and/or video phone.

In the step S350, the mobile communication terminal (300) transmits the phone signal to the amp for vehicle (210) using the bluetooth module. The phone signal may be the audio signal transmitted to the amp for vehicle (210) corresponding to the phone-call data. In the step S360, the amp for vehicle (210) amplifies the received phone signal, and in the step S370 the amp for vehicle (210) transmits the amplified phone signal to the speaker (220).

Also, according to other embodiment of the present invention, the bluetooth module may be attached to the amp for vehicle detachably. That is, the bluetooth module with the above features may be attached to a regular amp for vehicle without bluetooth module and performs the features. The detachable bluetooth module is supplied with power from the amp for vehicle, provides devices such as a switch for determining whether audio signal is inputted or not for performing the above features, and can be attached to the amp for vehicle detachably. In such a case, the user with a regular amp for vehicle may purchase a bluetooth module and perform the above features by attaching it to the main body of the amp for vehicle.

Other than these, detailed explanations on a specific system structure, embedded system, common platform technology such as O/S and communication protocol, interface standard technology such as I/O interface and actuator, part standard technology for battery, camera, sensor, etc. for the amp system for vehicle using bluetooth module are omitted because they are obvious to one of ordinary skills in the community.

The operation method of the amp for vehicle using bluetooth module according to the present invention may be realized in forms of program commands that can be executed using various computer means and recorded in computer-readable media. That is, the computer-readable media may be a media that a computer having the program for performing the above steps recorded therein can read.

The computer-readable media may include program commands, data file, data structure, etc. separately or in combinations. The program commands recorded in the above media may be one that is designed and formed specially for the present invention or one that is well known to the computer software community and usable already. The computer-readable media includes hard disk, magnetic media such as floppy disk and magnetic tape, optical media such as CD-ROM and DVD, magneto-optical media such as floptical disk, and a hardware device such as ROM, RAM, flash memory, etc. that are formed especially for storing and executing the program commands.

Also, each of the above parts may be realized as a part neighboring physically, or as different parts. In the latter case, the parts may be attached contacting or detachably and positioned in different regions and controlled. If the parts are controlled in different regions, the invention may provide a separate control means or control room for controlling the parts by wire or wireless.

### INDUSTRIAL APPLICATIONS

As described in the above, the parts and/or functions explained in each embodiment may be combined together to be realized, and it will be appreciated by those skilled in the art that variations in form, detail, compositions and operation may be made without departing from the spirit and scope of the invention as defined by the accompanying claims.

1. An amp system for vehicle using bluetooth module, the amp system comprising:
a main body;
a power supply terminal disposed at a side of the main body and for receiving electric current from an external power source;
a bluetooth-receiving module for being powered by the electric current and receiving an audio signal from a bluetooth transmission module embedded in a mobile communication terminal of a user in a vehicle;
a PCB with a device for amplifying the received audio signal using the electric current;
an output terminal for delivering the amplified audio signal to a speaker; and
the speaker for receiving the amplified audio signal from the output terminal and generating sound.

2. The amp system for vehicle using bluetooth module of claim 1, wherein when the mobile communication terminal receives a phone-call data while transmitting a music signal for the audio signal, the mobile communication terminal stops the transmission of the music signal and transmits a phone-connecting sound or a phone-call sound data corresponding to the phone-call data to the bluetooth-receiving module for the audio signal.

3. The amp system for vehicle using bluetooth module of claim 2, further comprising a switch for activating or deactivating a function that when the mobile communication terminal receives a phone-call data while transmitting a music signal for the audio signal, the mobile communication terminal stops the transmission of the music signal and transmits a phone-connecting sound or a phone-call sound data corresponding to the phone-call data to the bluetooth-receiving module for the audio signal.

4. The amp system for vehicle using bluetooth module of claim 1, wherein the output terminal is a bluetooth module for transmitting a bluetooth signal, and wherein the output terminal and the speaker communicate with each other with the bluetooth module.

5. The amp system for vehicle using bluetooth module of claim 1, wherein the main body receives the PCB, is opened and closed by a main-body cover, provides heat sinks for radiating internal heat to outside on both sides thereof, and is installed in a trunk of the vehicle.

6. The amp system for vehicle using bluetooth module of claim 1, wherein the bluetooth receiving module is attached to the main body detachably.

7. An amp system for vehicle using bluetooth module, the amp system comprising:
a bluetooth-receiving module for receiving an audio signal from a bluetooth transmission module embedded in a mobile communication terminal of a user in a vehicle;
a PCB with a device for amplifying the received audio signal;
an output terminal for delivering the amplified audio signal to a speaker; and
the speaker for receiving the amplified audio signal from the output terminal and generating sound,
wherein when the mobile communication terminal receives a phone-call data while transmitting a music signal for the audio signal, the mobile communication terminal stops the transmission of the music signal and transmits a phone-connecting sound or a phone-call sound data corresponding to the phone-call data to the bluetooth-receiving module for the audio signal.

8. The amp system for vehicle using bluetooth module of claim 7, further comprising a switch for activating or deactivating a function that when the mobile communication terminal receives a phone-call data while transmitting a music signal for the audio signal, the mobile communication terminal stops the transmission of the music signal and transmits a phone-connecting sound or a phone-call sound data corresponding to the phone-call data to the bluetooth-receiving module for the audio signal.

9. The amp system for vehicle using bluetooth module of claim 7, wherein the output terminal is a bluetooth module for transmitting a bluetooth signal, and wherein the output terminal and the speaker communicate with each other with the bluetooth module.

10. The amp system for vehicle using bluetooth module of claim 7, wherein by installing the bluetooth module in the amp for vehicle and communicating with the mobile communication terminal of the user using bluetooth communication, the ampl system amplifies music or phone call sound from the mobile communication terminal through the amp for vehicle and outputs it through the speaker in vehicle.
